(19) United States
(12) Patent Application Publication
(10) Pub. No.: US 2026/0040715 A1
(43) Pub. Date: Feb. 5, 2026

(54) SILICON WAFER PRINTER FOR DOUBLE HALF-CELL PRINTING

(71) Applicant: Guangdong Kelongwei Automation Equipment Co., Ltd., Dongguan (CN)

(72) Inventors: Jincai SU, Dongguan (CN); Chunfu CHEN, Dongguan (CN)

(21) Appl. No.: 19/356,332

(22) Filed: Oct. 13, 2025

(30) Foreign Application Priority Data
Oct. 14, 2024 (CN) 202411432581.6

(51) Int. Cl. H10F 71/00; B41F 15/08; B41F 15/12; B41F 15/20; B41F 15/26; B41F 15/36; B41F 15/42; B41F 15/44; B41F 21/00; B41F 33/00

(52) U.S. Cl. CPC H10F 71/1375; B41F 15/0818; B41F 15/0863; B41F 15/12; B41F 15/20; B41F 15/26; B41F 15/36; B41F 15/423; B41F 15/44; B41F 21/00; B41F 33/00; B41P 2215/12; B41P 2215/50

(57) ABSTRACT

The present invention discloses a silicon wafer printer for double half-cell printing, comprising a work platform, a turntable assembly, a front-end conveyor, a left calibration module, and a right calibration module. A calibration vision camera is mounted above the front-end conveyor's end. The left linear module connects to a left motor module and then a left suction module. The right linear module connects to a right motor module, two calibration cylinders, calibration bearings, and a right suction module. It uses visual positioning to determine double half-cells' position/angle, adjusts the right half-cell with the left as reference, shortens alignment time, adopts single-head front-to-back printing and a smaller indexing disc, boosting turntable printing efficiency.

### CROSS-REFERENCE TO RELATED APPLICATIONS

This application claims the benefit of priority from Chinese Patent Application No. 202411432581.6, field on Oct. 14, 2024. The content of the aforementioned application, including any intervening amendments thereto, is incorporated by reference in its entirety.

### TECHNICAL FIELD

The present invention relates to the technical field of silicon wafer production, particularly to a silicon wafer printer for double half-cell printing.

### BACKGROUND

Photovoltaic solar silicon wafers (hereafter referred to as silicon wafers) constitute the core component of solar power generation systems and represent the most valuable part of solar power generation systems. The function of silicon wafers is to convert solar energy into electrical energy, and then electrical energy is stored in batteries or directly powers loads. In existing double half-cell printing processes, the double half-cells are first transferred from two front-end conveyors onto a turntable assembly, causing the steel screen to accurately align with the double half-cells on the turntable assembly through capturing and positioning of the camera and adjustment of the printing module. However, the slow adjustment speed of the printing module results in a slower alignment calibration process, thereby impacting printing efficiency.

### SUMMARY

One objective of the present invention is to provide a silicon wafer printer for double half-cell printing. Prior to transferring the double half-cells to the turntable assembly, two calibration modules perform alignment: the left calibration module serves as the reference, while the right calibration module performs angular correction, saving subsequent alignment time and improving printing efficiency.

To achieve this objective, the present invention employs the following technical solutions:

A silicon wafer printer for double half-cell printing, comprising a work platform, a turntable assembly, a front-end conveyor, a left calibration module, and a right calibration module. The turntable assembly is positioned at the center of the work platform, and the front-end conveyor is located on one side of the work platform, with the left and right alignment modules positioned on opposite sides of the front-end conveyor. A calibration vision camera is mounted above the end of the front-end conveyor.

The left calibration module comprises a left linear module, with a left motor module connected to the drive end of the left linear module. The drive end of the left motor module is vertically connected to a left suction module;

The right calibration module comprises a right linear module, with a right motor module connected to the drive end of the right linear module. Two calibration cylinders are connected to the drive end of the right motor module, and the two calibration cylinders are arranged in parallel. The drive ends of the calibration cylinders connect downward to calibration bearings, with the two calibration bearings jointly connecting to a right suction module.

As a preferred technical solution, a clamping motor is mounted on the front-end conveyor, the drive end of the clamping motor being keyed to a clamping synchronizing wheel, the clamping synchronizing wheel being connected to a clamping synchronizing belt in a transmission way, and a clamping rod is fixed to the clamping synchronizing belt.

As a preferred technical solution, a back-end conveyor is included, the back-end conveyor is provided with a fragment lifting cylinder, the drive end of the fragment lifting cylinder is connected upward to a fragment lifting plate. Both sides of the fragment lifting plate extend beyond the outer edges of the back-end conveyor. A detection bracket is mounted at the rear end of the back-end conveyor, with a sensor mounted atop the detection bracket. The sensor is positioned above the back-end conveyor and the sensor is used to detect whether wafer jams occur in the reflow oven.

As a preferred technical solution, it includes a printing module. The lower end of the printing module is provided with one X-axis module and two Y-axis modules. The one X-axis module and the two Y-axis modules are jointly connected to a screen installation frame.

As a preferred technical solution, lifting modules are arranged on both sides at the rear end of the work platform, the lifting module comprises a side bracket, a lifting servo motor is mounted at the upper end of the side bracket, and the drive end of the lifting servo motor is connected to a lifting ball screw. Both sides of the printing module are connected to lifting plates, with lifting ball nuts fixed to the outer sides of the lifting plates. The lifting ball screw is threadedly connected to the lifting ball nut, and the lifting plate slides vertically along the side bracket. The side bracket is provided with a lifting guide rail, and the outer side of the lifting plate is fixed with a lifting slider, and the lifting slider slides along the lifting guide rail.

As a preferred technical solution, a squeegee linear module is mounted on the printing module, and the squeegee linear module comprises a profile base, an adapter plate, and an electrical mounting plate. The electrical mounting plate houses electrical components and a drag chain. The both sides of lower ends of the adapter plate slide along the front-to-back direction relative to the profile base via guide rails and sliders. The adapter plate is fixed to one side of the electrical mounting plate and the adapter plate locks the printing kit in place.

As a preferred technical solution, the drive end of the squeegee linear module is connected with the squeegee front-to-back moving plate, the printing kit is fixed on one side of the squeegee front-to-back moving plate, the printing kit has a stock squeegee connected to its lower end, and a squeegee motor is mounted on the upper end of the printing kit. The squeegee motor controls the vertical movement of the stock squeegee via a ball screw and ball nut. The lower end of the printing kit is further connected to an ink reclaiming blade. The upper end of the printing kit is additionally equipped with an ink reclaiming motor. The ink reclaiming motor also controls the vertical movement of the ink reclaiming blade holder of the ink reclaiming blade via a ball screw and ball nut. Both ends of the ink reclaiming blade are respectively locked at both ends of the ink reclaiming blade holder.

As a preferred technical solution, the X-axis module and the Y-axis module utilize the same modular mechanism, the module mechanism comprises a module base plate, a module motor, an adjustment lead screw, and an adjustment sliding table. The drive end of the module motor is connected to the adjustment lead screw in a transmission way, the adjustment lead screw is threadedly connected to an adjustment nut beneath the adjustment sliding table, and the adjustment sliding table slides along the length of the adjustment lead screw. A connecting bearing is arranged on the adjustment sliding table, and the connecting bearing slides along the adjustment sliding table, with the movement direction of the connecting bearing being mutually perpendicular to that of the adjustment sliding table, wherein the edge of the steel mesh frame is locked within the connecting bearing.

As a preferred technical solution, the turntable assembly comprises a circular turntable, an integrated electrical slip ring, and a turntable motor. Four positions are mounted around the periphery of the circular turntable, and each of the positions is provided with two half-cell printing positions. The drive end of the turntable motor vertically connects upward to the integrated electrical slip ring, the central portion of the circular turntable connects to the integrated electrical slip ring, and the lower end of the circular turntable rotatably connects to a roll paper transport component. The roll paper transport component comprises an unwinding shaft and a winding shaft. A roll paper is connected between the unwinding shaft and the winding shaft in a transmission way. The roll paper passes through the half-cell printing position and carries silicon wafers to transport silicon wafers. The roll paper is permeable. The roll paper transport component conveys silicon wafers to the positions on the circular turntable and transports them to the printing position of output silicon wafers of double half-cell precision steel screen printer.

As a preferred technical solution, the locations between the four positions of the circular turntable form sector-shaped regions. These regions, together with the central location of the circular turntable, store electrical components and control assemblies, and are covered by a protective cap. Each of the half-cell printing positions is provided with a vented vacuum plate. The vented vacuum plate is provided with a plurality of air holes, and the air holes, through a roll paper, adsorb and fix the silicon wafer at the half-cell printing position.

The beneficial effects of the present invention are as follows: A silicon wafer printer for double half-cell printing is provided. The silicon wafer printer for double half-cell printing determines the position and angle of double half-cells through visual positioning at the end of the conveyor, and with the left half-cell as a reference, controls the right half-cell adjustment angle, and after being flush with the left half-cell, moves together onto the turntable assembly for printing, significantly reducing double half-cell alignment time, saving the action of steel screen correction, and accelerating printing efficiency on the turntable assembly.

### BRIEF DESCRIPTION OF THE DRAWINGS

The present invention will now be described in further detail with reference to the drawings and embodiments.

FIG. 1 is a top view of the silicon wafer printer for double half-cell printing according to the embodiment;

FIG. 2 is a first combined structure diagram of the front-end conveyor, left calibration module, and right calibration module according to the embodiment;

FIG. 3 is a second combined structure diagram of the front-end conveyor, left calibration module, and right calibration module according to the embodiment;

FIG. 4 is a structural diagram of the right calibration module according to the embodiment;

FIG. 5 is a structural diagram of the left calibration module according to the embodiment;

FIG. 6 is a front space diagram of the turntable assembly according to the embodiment;

FIG. 7 is a front view of the turntable assembly according to the embodiment;

FIG. 8 is a middle flipping diagram of the turntable assembly according to the embodiment;

FIG. 9 is a front space diagram of the printing module according to the embodiment;

FIG. 10 is a bottom view of the printing module according to the embodiment;

FIG. 11 is an exploded view of the X-axis module/Y-axis module according to the embodiment;

FIG. 12 is a three-dimensional structure diagram of the lifting module according to the embodiment;

FIG. 13 is a structural diagram of the printing kit according to the embodiment;

FIG. 14 is an exploded view of the printing kit according to the embodiment;

FIG. 15 is a structural diagram of the back-end conveyor according to the embodiment.

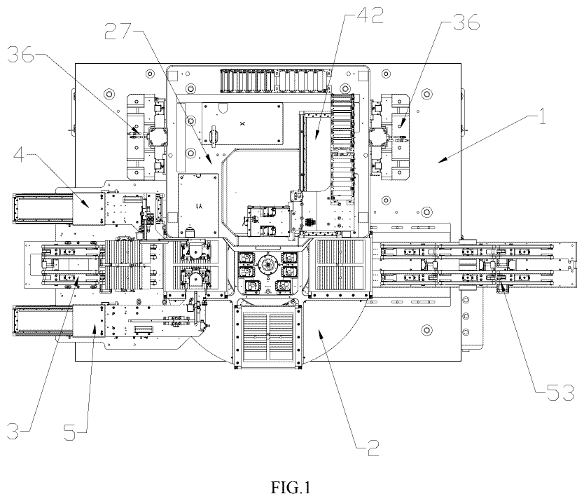

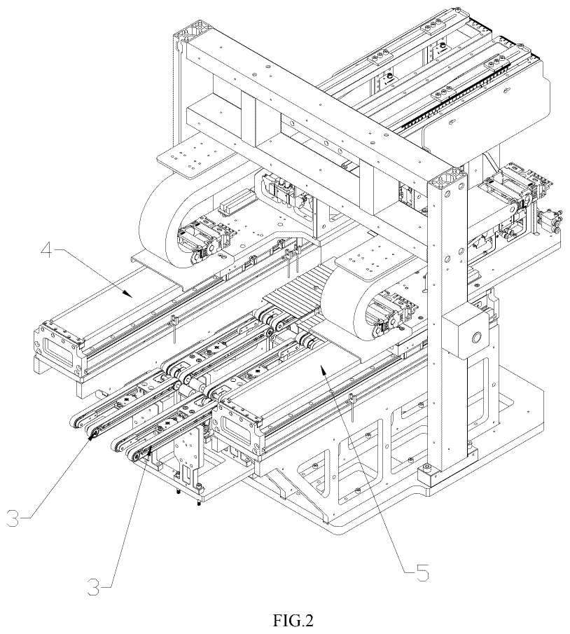

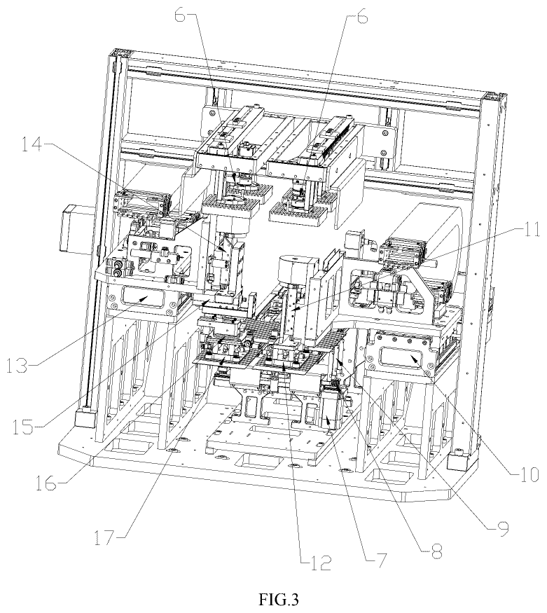

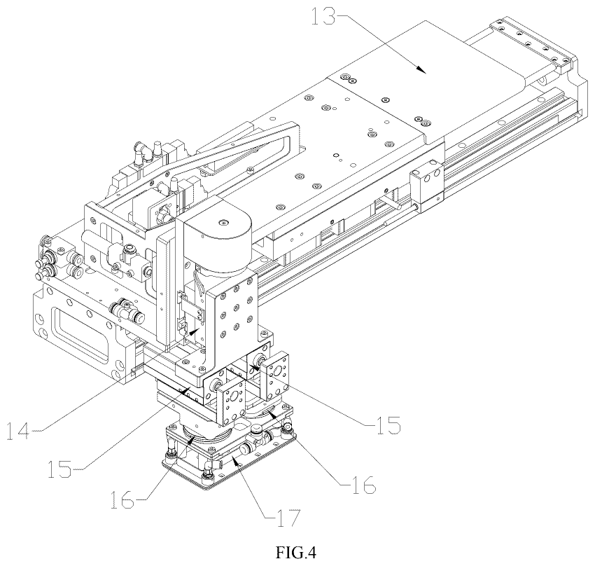

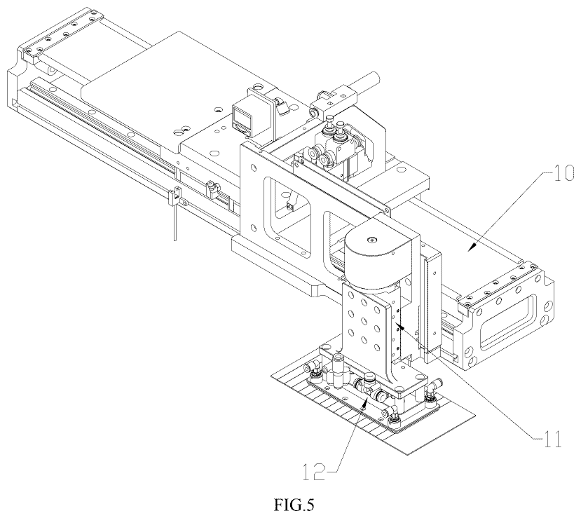

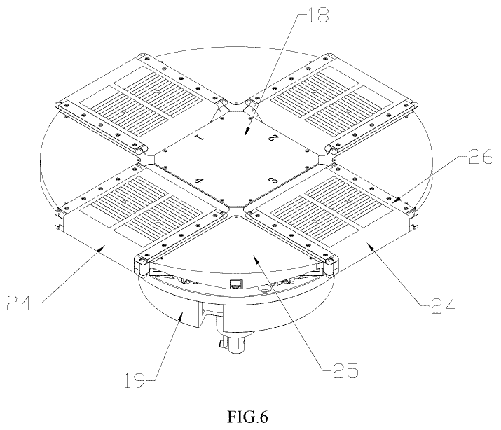

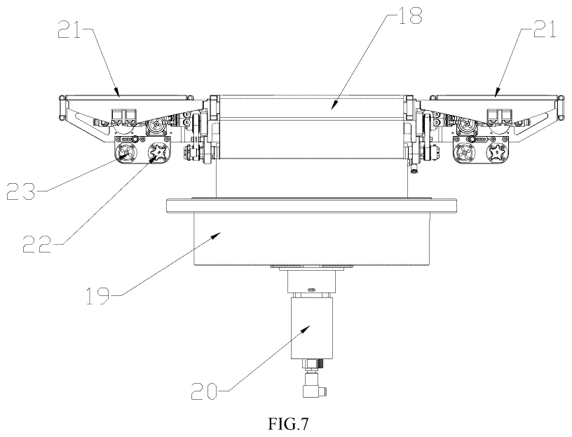

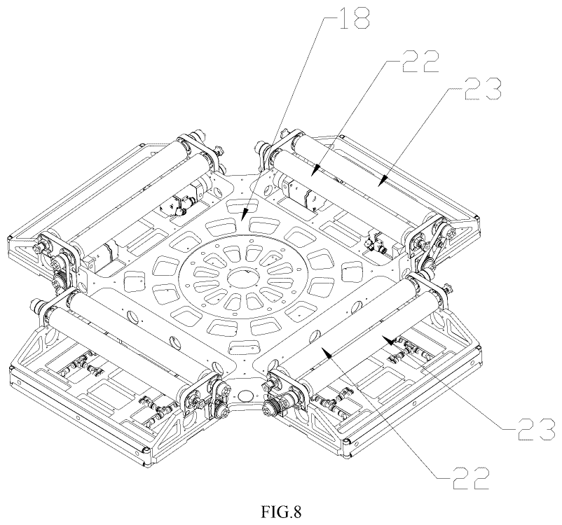

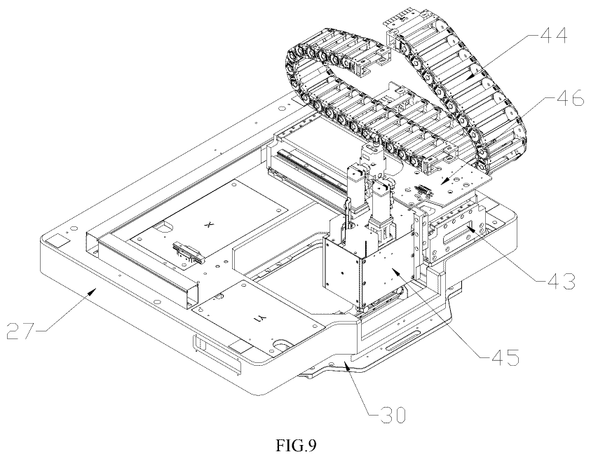

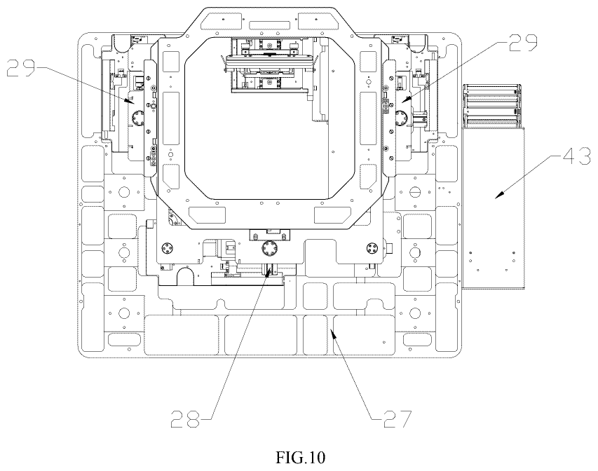

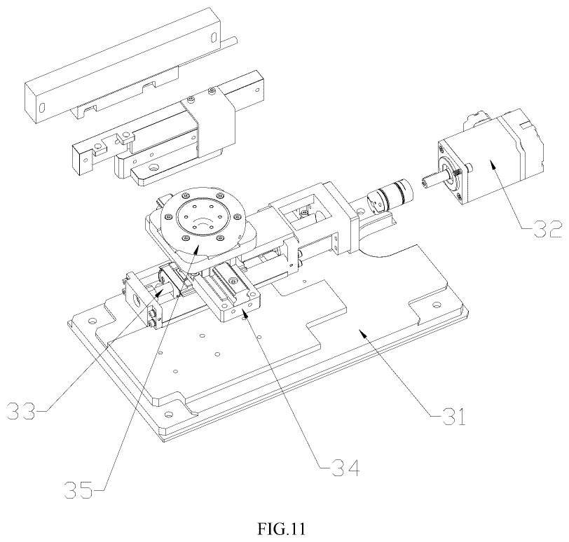

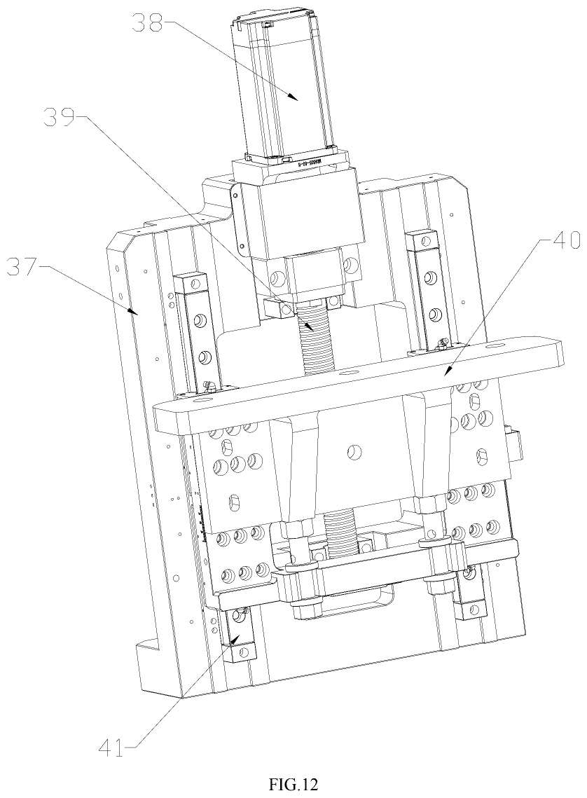

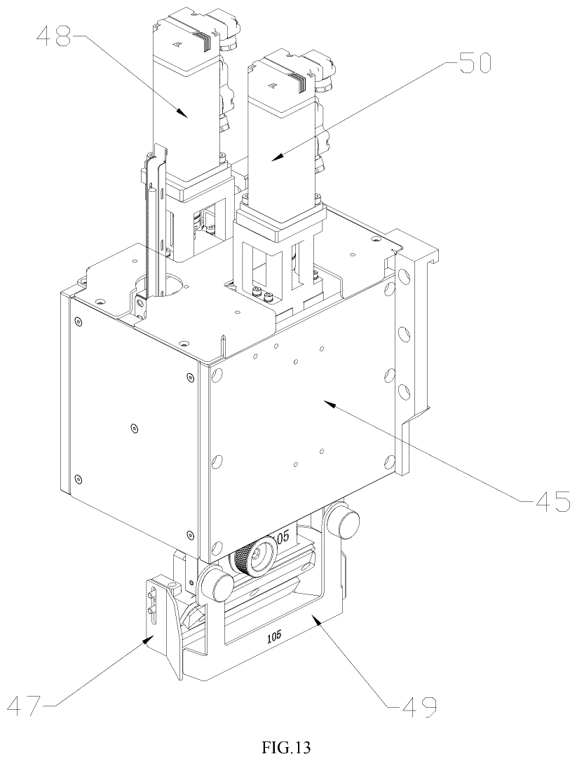

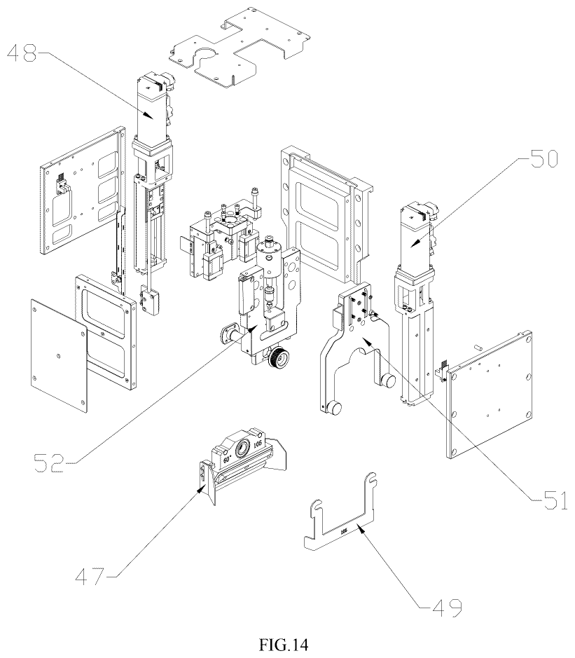

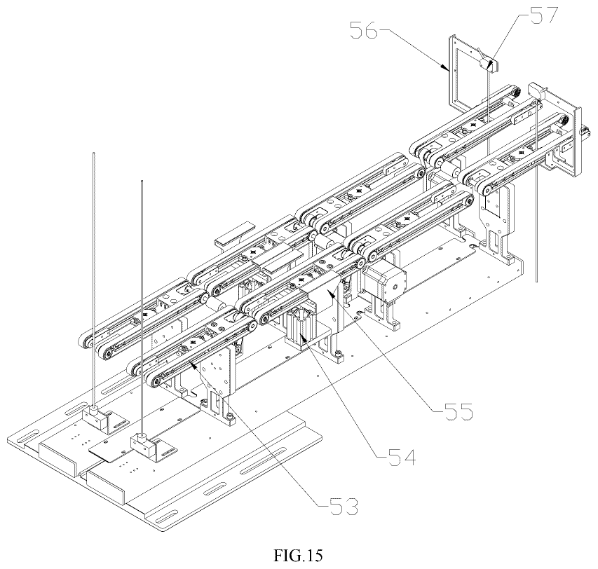

In FIGS. 1 to 15:
1. Work platform; 2. Turntable assembly; 3. Front-end conveyor; 4. Left calibration module; 5. Right calibration module; 6. Calibration vision camera; 7. Clamping motor; 8. Clamping synchronizing wheel; 9. Clamping rod; 10. Left linear module; 11. Left motor module; 12. Left suction module; 13. Right linear module; 14. Right motor module; 15. Calibration cylinder; 16. Calibration bearing; 17. Right suction module; 18. Circular turntable; 19. Integrated electrical slip ring; 20. Turntable motor; 21. Half-cell printing position; 22. Unwinding shaft; 23. Winding shaft; 24. Roll paper; 25. Protective cap; 26. Vented vacuum plate; 27. Printing module; 28. X-axis module; 29. Y-axis module; 30. Steel screen installation frame; 31. Module base plate; 32. Module motor; 33. Adjustment lead screw; 34. Adjustment sliding table; 35. Connecting bearing; 36. Lifting module; 37. Side bracket; 38. Lifting servo motor; 39. Lifting ball screw; 40. Lifting plate; 41. Lifting guide rail; 42. Squeegee linear module; 43. Profile base; 44. Drag chain; 45. Printing kit; 46. Front-to-back moving plate plates of squeegee; 47. Paste squeegee; 48. Squeegee motor; 49. Ink reclaiming blade; 50. Ink reclaiming motor; 51. Ink reclaiming blade holder; 52. Stock squeegee holder; 53. Back-end conveyor; 54. Fragment lifting cylinder; 55. Fragment lifting plate; 56. Detection bracket; 57. Sensor.

### DETAILED DESCRIPTION OF EMBODIMENTS

The technical solution of the present invention will be further explained by specific embodiments with reference to the attached drawings.

As shown in FIGS. 1 to 15, in this embodiment, a silicon wafer printer for double half-cell printing, including a work platform 1, a turntable assembly 2, a front-end conveyor 3, a left calibration module 4, and a right calibration module 5. The turntable assembly 2 is positioned at the center of the work platform 1, and the front-end conveyor 3 is located on one side of the work platform 1, with the left calibration module 4 and right calibration module 5 positioned on opposite sides of the front-end conveyor 3. A calibration vision camera 6 is mounted above the end of the front-end conveyor 3.

The front-end conveyor 3 transports the double half-cells backward from both rail sections. When the double half-cells reach the end of rails, the calibration vision camera 6 mounted on the camera frame captures images of the double half-cells on both rails. After determining their positions, the left calibration module 4 directly absorbs the left half-cell, while the right calibration module 5 adjusts the angle of the absorbed half-cell relative to the left half-cell. Subsequently, both sides are synchronously placed into the turntable assembly 2 without requiring further adjustment of the printing squeegee section, effectively enhancing printing efficiency and quality.

A clamping motor 7 is mounted on the front-end conveyor 3, the drive end of the clamping motor 7 being keyed to a clamping synchronizing wheel 8, the clamping synchronizing wheel 8 being connected to a clamping synchronizing belt in a transmission way, and a clamping rod 9 is fixed to the clamping synchronizing belt.

When a silicon wafer transported previously is in an uneven position, the clamping motor 7 drives the clamping synchronizing wheel 8 to rotate. This rotation drives the clamping synchronizing belt, causing the clamping rods 9 on both sides of the front-end conveyor 3 to converge toward the center, leveling the silicon wafer in the middle position of the front-end conveyor 3.

The left calibration module 4 comprises a left linear module 10, with a left motor module 11 connected to the drive end of the left linear module 10. The drive end of the left motor module 11 is vertically connected to a left suction module 12. The right calibration module 5 comprises a right linear module 13, with a right motor module 14 connected to the drive end of the right linear module 13. Two calibration cylinders 15 are connected to the drive end of the right motor module 14, and the two calibration cylinders 15 are arranged in parallel. The drive ends of the calibration cylinders 15 connect downward to calibration bearings 16, with the two calibration bearings 16 jointly connecting to a right suction module 17.

The left motor module 11 on the left linear module 10 controls the left suction module 12 to descend, lifts the left half-cell positioned on the left rail, and driven by the left linear module 10, transfers the half-cell to the loading position of the turntable assembly 2. The right motor module 14 on the right linear module 13 controls the right suction module 17 to descend, to pick up the right half-cell positioned on the right rail. Based on the positions of the left and right half-cells captured by the calibration camera 6, with the left half-cell as the reference, the two calibration cylinders 15 rotate the right suction module 17 to the correct angle through extension and retraction of their drive ends. Assisted by the calibration bearing 16 for turning, the right half-cell is aligned with the left half-cell. The right linear module 13 synchronizes with the left linear module 10 to transfer the right half-cell to the loading position of the turntable assembly 2.

The turntable assembly 2 comprises a circular turntable 18, an integrated electrical slip ring 19, and a turntable motor 20. Four positions are mounted around the periphery of the circular turntable 18, and each of the positions is provided with two half-cell printing positions 21. The drive end of the turntable motor 20 vertically connects upward to the integrated electrical slip ring 19, the central portion of the circular turntable 18 connects to the integrated electrical slip ring 19, and the lower end of the circular turntable 18 rotatably connects to a roll paper 24 transport component. The roll paper 24 transport component comprises an unwinding shaft 22 and a winding shaft 23. A roll paper 24 is connected between the unwinding shaft 22 and the winding shaft 23 in a transmission way. The roll paper 24 passes through the half-cell printing position 21 and carries silicon wafers to transport silicon wafers. The roll paper 24 is permeable. The roll paper 24 transport component conveys silicon wafers to the positions on the circular turntable 18 and transports them to the printing position of output silicon wafers of double half-cell precision steel screen printer.

The locations between the four positions of the circular turntable 18 form sector-shaped regions. These regions, together with the central location of the circular turntable 18, store electrical components and control assemblies, and are covered by a protective cap 25. Each of the half-cell printing positions 21 is provided with a vented vacuum plate 26. The vented vacuum plate 26 is provided with a plurality of air holes, and the air holes, through a roll paper 24, adsorb and fix the silicon wafer at the half-cell printing position 21.

Silicon wafers from the front-end conveyor 3 are placed onto the half-sheet printing position 21. The turntable motor 20 powers the electrical slip ring 19 to synchronously rotate the circular turntable 18 horizontally, moving the silicon wafers beneath the steel screen mounting frame 30. Simultaneously, printed silicon wafers are transferred from beneath the steel screen mounting frame 30 to the front of the back-end conveyor 53. The winding shaft 23 rotates synchronously with the unwinding shaft 22, using clean roll paper 24 to wipe up the printing position 21.

The silicon wafer printer for double half-cell printing includes a printing module 27. The lower end of the printing module 27 is equipped with one X-axis module 28 and two Y-axis modules 29. The one X-axis module 28 and two Y-axis modules 29 are jointly connected to a steel screen mounting frame 30. The X-axis module 28 and the Y-axis module 29 have a module mechanism, and the module mechanism comprises a module base plate 31, a module motor 32, an adjustment lead screw 33, and an adjustment sliding table 34. The drive end of the module motor 32 is connected to the adjustment lead screw 33 in a transmission way, the adjustment lead screw 33 is threadedly connected to an adjustment nut beneath the adjustment sliding table 34, and the adjustment sliding table 34 slides along the length of the adjustment lead screw 33. A connecting bearing 35 is arranged on the adjustment sliding table 34, and the connecting bearing 35 slides along the adjustment sliding table 34, with the movement direction of the connecting bearing 35 being mutually perpendicular to that of the adjustment sliding table 34, wherein the edge of the steel screen mounting frame 30 is locked within the connecting bearing 35.

Based on the position and angle of the left half-cell, the printing module 27 controls one X-axis module 28 and two Y-axis modules 29 via visual positioning, causing the steel screen mounting frame 30 to align with the position of the two half-cells. After descending onto the turntable assembly 2, the printing operation can proceed.

Lifting modules 36 are arranged on both sides at the rear end of the work platform 1, the lifting module 36 comprises a side bracket 37, a lifting servo motor 38 is mounted at the upper end of the side bracket 37, and the drive end of the lifting servo motor 38 is connected to a lifting ball screw 39. Both sides of the printing module 27 are connected to lifting plates 40, with lifting ball nuts fixed to the outer sides of the lifting plates 40. The lifting ball screw 39 is threadedly connected to the lifting ball nut, and the lifting plate 40 slides vertically along the side bracket 37. The side bracket 37 is provided with a lifting guide rail 41, and the outer side of the lifting plate 40 is fixed with a lifting slider, and the lifting slider slides along the lifting guide rail 41.

When controlling the vertical movement of the printing module 27, the lifting servo motor 38 drives the lifting ball screw 39 to rotate. The lifting plate 40, equipped with the lifting ball nut, moves the printing module 27 along the lifting guide rail 41, with enhanced precision and faster movement speeds.

A squeegee linear module 42 is mounted on the printing module 27, and the squeegee linear module 42 comprises a profile base 43, an adapter plate, and an electrical mounting plate 44. The electrical mounting plate 44 houses electrical components and a drag chain 45. The both sides of lower ends of the adapter plate slide along the front-to-back direction relative to the profile base 43 via guide rails and sliders. The adapter plate is fixed to one side of the electrical mounting plate 44 and the adapter plate locks the printing kit 46 in place.

The drive end of the squeegee linear module 42 is connected with the front and rear moving plates 47 of the squeegee, the printing kit 46 is fixed on one side of the front and rear moving plates 47 of the squeegee, the printing kit 46 has a stock squeegee 48 connected to its lower end, and a squeegee motor 49 is mounted on the upper end of the printing kit 46. The squeegee motor 49 controls the vertical movement of the stock squeegee 48 via a ball screw and ball nut. The lower end of the printing kit 46 is further connected to an ink reclaiming blade 50. The upper end of the printing kit 46 is additionally equipped with an ink reclaiming motor 51. The ink reclaiming motor 51 also controls the vertical movement of the ink reclaiming blade holder 52 of the ink reclaiming blade 50 via a ball screw and ball nut. Both ends of the ink reclaiming blade 50 are respectively locked at both ends of the ink reclaiming blade holder 52.

During paste scraping, the squeegee motor 49 controls the paste squeegee 48 to descend onto the steel screen. The squeegee linear module 42 drives the printing kit 46 synchronously via forward and backward movement of the squeegee front-to-back moving plate 47, causing the paste squeegee 48 to scrape paste from the steel screen onto the silicon wafer during its front and rear movement.

The silicon wafer printer for double half-cell printing includes a back-end conveyor 53, the back-end conveyor 53 is provided with a fragment lifting cylinder 54, and the drive end of the fragment lifting cylinder 54 is connected upward to a fragment lifting plate 55. Both sides of the fragment lifting plate 55 extend beyond the outer edges of the back-end conveyor 53. A detection bracket 56 is mounted at the rear end of the back-end conveyor 53, with a sensor mounted atop the detection bracket 56. The sensor 57 is positioned above the back-end conveyor 53 and the sensor 57 is used to detect whether wafer jams occur in the reflow oven.

When transferring or detecting silicon wafers on the back-end conveyor 53, the fragment lifting plate 55 can be raised via the fragment lifting cylinder 54 to isolate the silicon wafers for handling. At the end of the back-end conveyor 53, a sensor 57 detects the presence of silicon wafers to prepare for subsequent docking.

When transferring or detecting silicon wafers on the back-end conveyor 53, the fragment lifting plate 55 can be raised via the fragment lifting cylinder 54 to isolate the silicon wafers for handling. At the end of the back-end conveyor 53, a sensor 57 detects the presence of silicon wafers to prepare for subsequent docking.

What is claimed is:

1. A silicon wafer printer for double half-cell printing, comprising a work platform, a turntable assembly, a front-end conveyor, a left calibration module, and a right calibration module; the turntable assembly is positioned at the center of the work platform, and the front-end conveyor is located on one side of the work platform, with the left and right alignment modules positioned on opposite sides of the front-end conveyor; a calibration vision camera is mounted above the end of the front-end conveyor;
the left calibration module comprises a left linear module, with a left motor module connected to the drive end of the left linear module; the drive end of the left motor module is vertically connected to a left suction module;
the right calibration module comprises a right linear module, with a right motor module connected to the drive end of the right linear module; two calibration cylinders are connected to the drive end of the right motor module, and the two calibration cylinders are arranged in parallel; The drive ends of the calibration cylinders connect downward to calibration bearings, with the two calibration bearings jointly connecting to a right suction module;
a clamping motor is mounted on the front-end conveyor, the drive end of the clamping motor being keyed to a clamping synchronizing wheel, the clamping synchronizing wheel being connected to a clamping synchronizing belt in a transmission way, and a clamping rod is fixed to the clamping synchronizing belt;
a printing module is further included; the lower end of the printing module is provided with one X-axis module and two Y-axis modules; the one X-axis module and the two Y-axis modules are jointly connected to a screen installation frame;
the turntable assembly comprises a circular turntable, an integrated electrical slip ring, and a turntable motor; four positions are mounted around the periphery of the circular turntable, and each of the positions is provided with two half-cell printing positions; the drive end of the turntable motor vertically connects upward to the integrated electrical slip ring, the central portion of the circular turntable connects to the integrated electrical slip ring, and the lower end of the circular turntable rotatably connects to a roll paper transport component; the roll paper transport component comprises an unwinding shaft and a winding shaft; a roll paper is connected between the unwinding shaft and the winding shaft in a transmission way; the roll paper passes through the half-cell printing position and carries silicon wafers to transport silicon wafers; the roll paper is permeable; the roll paper transport component conveys silicon wafers to the positions on the circular turntable and transports them to the printing position of output silicon wafers of double half-cell precision steel screen printer.

2. A silicon wafer printer for double half-cell printing as claimed in claim 1, wherein a back-end conveyor is included, the back-end conveyor is provided with a fragment lifting cylinder, the drive end of the fragment lifting cylinder is connected upward to a fragment lifting plate; both sides of the fragment lifting plate extend beyond the outer edges of the back-end conveyor; a detection bracket is mounted at the rear end of the back-end conveyor, with a sensor mounted atop the detection bracket; The sensor is positioned above the back-end conveyor and the sensor is used to detect whether wafer jams occur in the reflow oven.

3. A silicon wafer printer for double half-cell printing as claimed in claim 1, wherein lifting modules are arranged on both sides at the rear end of the work platform, the lifting module comprises a side bracket, a lifting servo motor is mounted at the upper end of the side bracket, and the drive end of the lifting servo motor is connected to a lifting ball screw; both sides of the printing module are connected to lifting plates, with lifting ball nuts fixed to the outer sides of the lifting plates; the lifting ball screw is threadedly connected to the lifting ball nut, and the lifting plate slides vertically along the side bracket; The side bracket is provided with a lifting guide rail, and the outer side of the lifting plate is fixed with a lifting slider, and the lifting slider slides along the lifting guide rail.

4. A silicon wafer printer for double half-cell printing as claimed in claim 3, wherein a squeegee linear module is mounted on the printing module, the squeegee linear module comprises a profile base, an adapter plate, and an electrical mounting plate; the electrical mounting plate houses electrical components and a drag chain; the both sides of lower ends of the adapter plate slide along the front-to-back direction relative to the profile base via guide rails and sliders; the adapter plate is fixed to one side of the electrical mounting plate and the adapter plate locks the printing kit in place.

5. A silicon wafer printer for double half-cell printing as claimed in claim 4, wherein the drive end of the squeegee linear module is connected with the squeegee front-to-back moving plate, the printing kit is fixed on one side of the squeegee front-to-back moving plate, the printing kit has a stock squeegee connected to its lower end, and a squeegee motor is mounted on the upper end of the printing kit; the squeegee motor controls the vertical movement of the stock squeegee via a ball screw and ball nut; the lower end of the printing kit is further connected to an ink reclaiming blade; the upper end of the printing kit is additionally equipped with an ink reclaiming motor; the ink reclaiming motor also controls the vertical movement of the ink reclaiming blade holder of the ink reclaiming blade via a ball screw and ball nut; both ends of the ink reclaiming blade are respectively locked at both ends of the ink reclaiming blade holder.

6. A silicon wafer printer for double half-cell printing as claimed in claim 1, wherein the X-axis module and the Y-axis module have module mechanisms, the module mechanism comprises a module base plate, a module motor, an adjustment lead screw, and an adjustment sliding table; the drive end of the module motor is connected to the adjustment lead screw in a transmission way, the adjustment lead screw is threadedly connected to an adjustment nut beneath the adjustment sliding table, and the adjustment sliding table slides along the length of the adjustment lead screw; a connecting bearing is arranged on the adjustment sliding table, and the connecting bearing slides along the adjustment sliding table, with the movement direction of the connecting bearing being mutually perpendicular to that of the adjustment sliding table, wherein the edge of the steel screen mounting frame is locked within the connecting bearing.

7. A silicon wafer printer for double half-cell printing as claimed in claim 1, wherein the locations between the four positions of the circular turntable form sector-shaped regions; these regions, together with the central location of the circular turntable, store electrical components and control assemblies, and are covered by a protective cap; each of the half-cell printing positions is provided with a vented vacuum plate; the vented vacuum plate is provided with a plurality of air holes, and the air holes, through a roll paper, adsorb and fix the silicon wafer at the half-cell printing position.
